(19) United States
(12) Patent Application Publication
(10) Pub. No.: US 2008/0211605 A1
(43) Pub. Date: Sep. 4, 2008

(54) Coupling Lines For a Yig Filter or Yig Oscillator and Method For Producing the Coupling Lines

(75) Inventors: Wilhelm Hohenester, Munchen (DE); Claus Tremmel, Haar (DE)

Correspondence Address: MARSHALL, GERSTEIN & BORUN LLP, 233 S. WACKER DRIVE, SUITE 6300, SEARS TOWER, CHICAGO, IL, 60606, US

(73) Assignee: ROHDSE & SCHWARZ GMBH & CO. KG, MUNCHEN (DE)

(21) Appl. No.: 11/667,897

(22) PCT Filed: Nov. 7, 2005
(86) PCT No.: PCT/EP2005/011885

§ 371 Date: Nov. 5, 2007

(30) Foreign Application Priority Data
Nov. 22, 2004 (DE) 10 2004 056 259.8

(51) Int. Cl. H01P 1/20; C23C 14/32

(52) U.S. Cl. 333/238; 204/192.32

(57) ABSTRACT

A coupling conductor for a YIG filter or YIG oscillator, which may be produced from a metallic foil by eroding, laser cutting and/or etching of a metallic foil. The coupling conductor includes at least one curved section, which at least partially surrounds a YIG element and at least one conductor section.

The invention relates to coupling lines for use in a YIG band-pass filter or a YIG oscillator according to the preamble of claim 1 and a method for producing such coupling lines, suitable for use in a YIG band-pass filter or a YIG oscillator, according to the preamble of claim 11.

YIG band-pass filters or YIG oscillators have at least one resonator, which is preferably constructed as spherical and made from an yttrium iron garnet YIG). The resonator action is conveyed by means of coupling lines which must be constructed and arranged in such a way that the center point of the resonator and the center point of the bend radius of a coupling line match exactly.

A YIG band-pass filter with appropriately constructed coupling lines is known from document U.S. Pat. No. 4,480,238, for example. The variable frequency YIG band-pass filter here has a basic body, comprising slits for accommodating insulated chips which have a conductive coating on one edge, which acts as coupling lines. Furthermore, filter chambers are provided to accommodate the YIG elements. The chips are inserted in the slits via the YIG elements in such a way that the YIG elements are arranged in indentations in the edges provided with the conductive coating. The YIG elements and the chips are fixed in permanent positions.

A disadvantage of the YIG band-pass filter known from the aforementioned document is, in particular, the complicated production of the chips forming the coupling lines. The insulator acting as support must first be appropriately formed and then provided with the conducting coating. This is complicated and liable to rejects, as the coating is susceptible to damage, owing to its small layer thickness.

The object of the present invention is therefore to create coupling lines which are easy to produce, unsusceptible to damage and easy to install and also to cite a method for producing such coupling lines.

The object is achieved in relation to the coupling lines by the characterizing features of claim 1, in relation to the method by the characterizing features of claim 11 and in relation to a foil support for the coupling lines by the characterizing features of claim 19.

Advantageous further developments of the coupling lines according to the invention and of the support according to the invention and the method according to the invention for producing the coupling lines are cited in the subordinate claims.

Preferred embodiment examples of the invention are illustrated below as examples using the drawings and explained in greater detail in the following description.

FIG. 1A shows a schematic, perspective illustration of a preferred embodiment example of a basic body of a YIG band-pass filter with resonators and coupling lines.

FIG. 1B shows a schematic, perspective illustration of the resonators and coupling lines without the basic body.

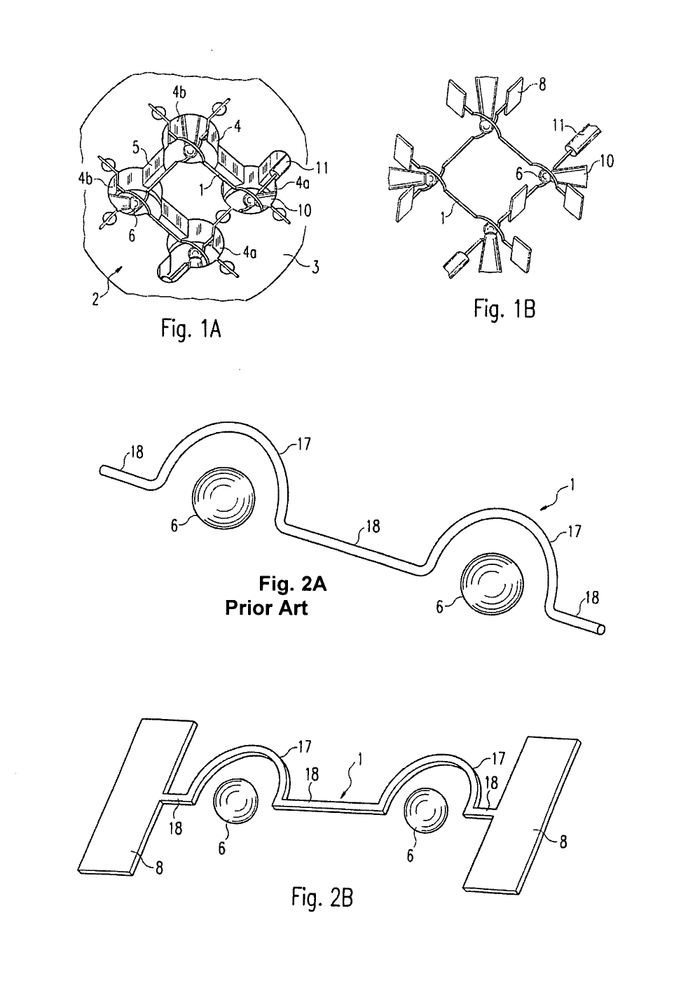

FIG. 2A shows a schematic illustration of a coupling loop as an example for two resonators according to the prior art.

FIG. 2B shows a schematic illustration of an embodiment example of a coupling loop configured according to the invention for two resonators.

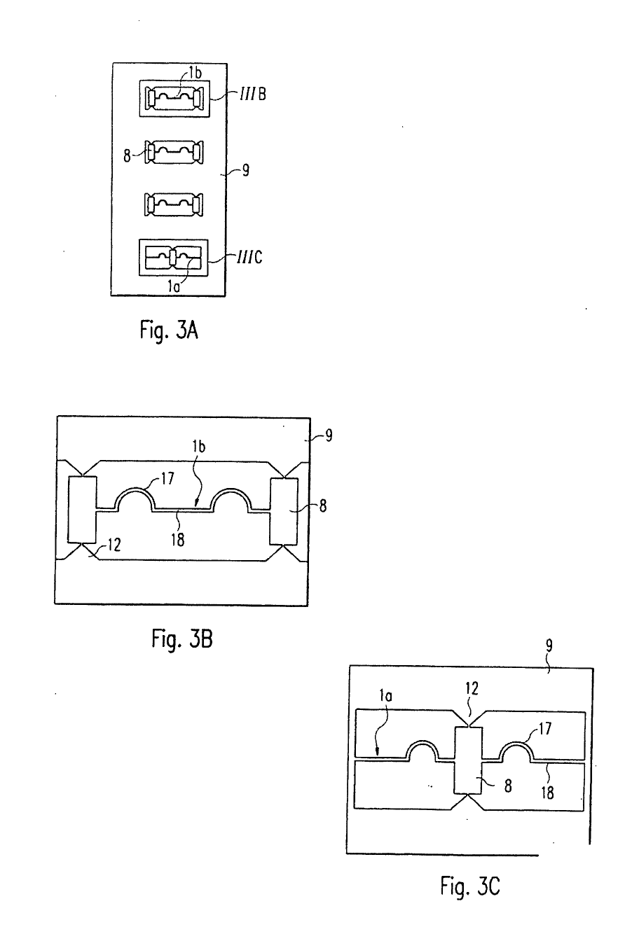

FIG. 3A-C show schematic illustrations of coupling lines configured according to the invention during the production process before detaching.

FIG. 1A shows in a schematic, perspective view an embodiment example of a YIG band-pass filter 2, having a basic body 3 and in the embodiment example four filter chambers 4, constructed in the basic body 3, with the same number of YIG elements 6.

The YIG elements 6 are in this case constructed as spherical from an yttrium iron garnet, mounted on holders 10, by gluing with epoxy resin, for example, and electromechanically coupled by coupling lines 1.

The filter chambers 4 are connected to one another by slits 5, into which the coupling lines 1 are placed. In the embodiment example two of the filter chambers 4 are constructed identically in each case. Coaxial cables 11, via which signals come in and go out, run into the filter chambers 4 designated as 4a. The filter chambers 4 designated as 4b, on the other hand, have only the YIG elements 6. The number of filter chambers 4b is not restricted to two, but may also amount to one or more, so the total number of filter chambers 4 may amount to either three or five or more.

FIG. 1B shows for better understanding of the measures according to the invention the arrangement of coupling lines 1 and the YIG elements 6 mounted on their holders 10 without the surrounding basic body 3.

In the embodiment example the coupling lines 1 are designed in two different forms. The coupling line 1 mutually connecting the filter chambers 4b is designed as an input and output line 1a, while the, in the embodiment example three, further coupling lines 1 are designed as connecting lines 1b.

As emerges from FIG. 1B, the coupling lines 1 have contact lugs 8, which on the one hand act as bonding point of the coupling lines 1 in the basic body 3 and on the other hand as fixing of the coupling lines 1 in the slits 5. The contact lugs 8 are formed rectangularly, one edge length of the contact lugs 8 corresponding to approximately the axial thickness of the basic body 2.

If one looks at FIGS. 2A and 2B, it is possible to see in what way the coupling lines 1 according to the invention according to FIG. 2B differ from conventional coupling lines 1 according to FIG. 2A.

The two embodiments have in common the fact that in each case at least one curved section 17 is provided, which in each case at least partially encompasses a YIG element 6 in such a way that a center point of the YIG element 6 coincides with a center point of the curved section 17. Furthermore, at least one line section 18 is provided.

The coupling line 1 according to the prior art illustrated in FIG. 2A is bent from a wire. The YIG elements 6 are here firstly inserted into the basic body 3, not illustrated in greater detail in FIGS. 2A and 2B, and the wire, pre-bent only roughly, is placed into the slits 5. A measurement of the degree of coupling then shows where the coupling line 1 still needs to be further bent. This is done manually by means of a suitable tool. After this there must by renewed checking and sometimes there needs to be further adjustment. For this purpose the YIG filter 2 or YIG oscillator has to be opened and then reassembled each time to perform the measurement. The method is therefore extremely complicated and often even results in the workpiece having to be completely rejected after several iterations, because no satisfactory coupling is achieved.

By contrast, the coupling lines 1 configured according to the invention according to FIG. 2B are made of a metal foil 7 by suitable methods, such as etching, eroding, cutting, in particular laser cutting or water-jet cutting, and/or blanking, and mounted. Correct positioning of the YIG elements 6 relative to the coupling lines 1 then takes place.

The foil 7 consists of a copper-beryllium alloy, in order to meet both the requirements for elasticity and for stability. The thickness of the foil 7 amounts to preferably approximately 50 μm.

Production of the coupling lines 1 from the foil 7 is done in several processing steps. Firstly the foil 7 is cleaned and then a positive resist is applied to both sides at an adjustment accuracy of approximately 5 μm in a layer thickness of approximately 5 μm, to create a mask. This is followed by the production of the coupling lines 1, for example by sputter etching with iron chloride (FeCl3). Then the foils in the form of a support 9 with a previously established number of coupling lines 1 are freed of remnants of varnish and provided galvanically with a gold coating of approximately 5 μm. Then a hardening process takes place for an hour at 325° C., for example. The coupling lines can then be released from the foil support 9 and built in.

Because of the production method described, the coupling lines 1 have a permanent shape with a precisely defined radius of curvature in the curved sections 17 with even curvature. The YIG elements 6 are then aligned relative to the coupling lines 1. This is simpler than the prior art and associated with an appreciably smaller outlay, because the accuracy of production with the coupling lines 1 configured according to the invention is appreciably greater than with manually bent coupling lines 1.

FIG. 3A shows in a schematic illustration a support 9 containing the coupling lines 1 required for a YIG band-pass filter 2 with four YIG elements 6.

As already mentioned above, in the embodiment example the coupling lines 1 are in the form of an input and output line 1a and three connecting lines 1b. The former is arranged right at the bottom of the foil support 9 in FIG. 3A and the latter above it.

FIGS. 3B and 3C show the parts cut out of the support 9 designated as IIIB and IIIC in FIG. 3A. In FIG. 3B one of the three connecting lines 1b is illustrated, while FIG. 3C shows the input and output line 1a.

It can be seen from FIGS. 3B and 3C that the coupling lines 1 are held in the support 9, after the process of etching, cutting, blanking or eroding from the foil 7 before being detached, by webs 12 which are constructed on the contact lugs 8. When the coupling lines 1 are detached the coupling lines 1 are separated from the support 9 by breaking the webs 12. After detaching, the coupling lines 1 are mounted in the basic body 3 according to their shape and fixed in the basic body 3 by soldering, welding or some other connecting method which maintains the electric conductivity.

The invention is not confined to the embodiment example illustrated and is suitable for YIG filters 2 or YIG oscillators configured in any way. The individual features can be combined with one another in any way.

1. Coupling line for a YIG filter or YIG oscillator with a coupling line, the coupling line having at least one curved section, which at least partially encompasses at least one YIG element, and at least one line section, the coupling line having at least one contact lug constructed in one piece with it,
wherein
the contact lug acts on the one hand as bonding point of the coupling line in a basic body and on the other hand as fixing for the coupling line in slits in the basic body.

2. Coupling line according to claim 1,
wherein
the at least one contact lug has a rectangular shape.

3. Coupling line according to claim 2,
wherein
an edge length of the at least one contact lug corresponds to approximately an axial thickness of the basic body of the YIG filter or YIG oscillator.

4. Coupling line according to claim 1, wherein
the coupling line is constructed as an input and output line or as a connecting line.

5. Coupling line according to claim 1,
wherein
the foil comprises an alloy of copper and beryllium.

6. Coupling line according to claim 5,
wherein
the thickness of the foil is in the range of 10 μm to 100 μm.

7. Coupling line according to claim 1, wherein
the at least one curved section of the coupling line has a defined reproducible radius of curvature.

8. Coupling line according to claim 1, wherein
the coupling line is produced by at least one of eroding, cutting, blanking and etching from a metal foil.

9. Method for producing a coupling line for a YIG filter or a YIG oscillator, the coupling line having at least one curved section, which at least partially encompasses at least one YIG element, and at least one line section, and the coupling line being made of a metal foil,
said method comprising producing the coupling line by at least one of eroding, cutting, blanking and etching.

10. Method according to claim 9,
comprising producing the coupling line by sputter etching using iron chloride (FeCl₃).

11. Method according to claim 9,
wherein
the method comprises the following method steps:
cleaning a foil,
varnishing the foil
sputter etching the coupling lines from the foil,
removing the varnish from the coupling lines,
gilding the coupling lines,
hardening the coupling lines and
detaching the coupling lines from the foil.

12. Method according to claim 11,
wherein
the step of varnishing the foil comprises varnishing a front and a back of the foil.

13. Method according to claim 11,
wherein
the thickness of the varnish during varnishing is approximately 5 μm.

14. Method according to claim 13,
wherein
the adjustment accuracy to the varnishing amounts to approximately 5 μm.

15. Method according to claim 12, comprising applying
the varnish in the form of positive resist.

16. Method according to claim 11,
wherein
the step of gilding takes place up to a layer thickness of approximately 5 μm.

17. Method according to claim 11,
comprising carrying out
the step of hardening for the duration of approximately one hour at a temperature of approximately 325° C.

18. Method according to claim 11, comprising producing
the coupling lines for a basic body of a YIG band-pass filter or YIG oscillator in each case as a unit in a foil support.

19. Foil support for coupling lines for YIG filters or YIG oscillators, the coupling lines having at least one curved section, which encompasses at least one YIG element, and at least one line section,
and the foil support containing as many coupling lines in each case as required for equipping a YIG filter or the YIG oscillator,
wherein
the coupling lines are held in the foil support by webs.

20. Coupling line according to claim 5, wherein the thickness of the foil is in the range of 25 μm to 75 μm.

21. Coupling line according to claim 5, wherein the thickness of the foil is about 50 μm.
